(19) United States
(12) Patent Application Publication
(10) Pub. No.: US 2024/0105842 A1
(43) Pub. Date: Mar. 28, 2024

(54) METHOD OF MANUFACTURING A SEMICONDUCTOR DEVICE

(71) Applicant: Samsung Electronics Co., Ltd., Suwon-si (KR)

(72) Inventors: Sunghwan JANG, Suwon-si (KR); Dohee KIM, Suwon-si (KR); Pyung MOON, Suwon-si (KR); Sunguk JANG, Suwon-si (KR); Mina SEOL, Suwon-si (KR)

(73) Assignee: Samsung Electronics Co., Ltd., Suwon-si (KR)

(21) Appl. No.: 18/456,934

(22) Filed: Aug. 28, 2023

(30) Foreign Application Priority Data
Sep. 23, 2022 (KR) 10-2022-0120653

(51) Int. Cl. H01L 29/78; H01L 21/02; H01L 21/308; H01L 29/40

(52) U.S. Cl. CPC H01L 29/7827; H01L 21/02532; H01L 21/308; H01L 29/401

(57) ABSTRACT

In a method of manufacturing a semiconductor device, a first selective epitaxial growth (SEG) process is performed on a substrate to form a first channel. A first etching process is performed to form a first recess through the first channel and an upper portion of the substrate. A sidewall of the first channel exposed by the first recess is slanted with respect to an upper surface of the substrate. A second SEG process is performed to form a second channel on a surface of the substrate and the sidewall of the first channel exposed by the first recess. A gate structure is formed to fill the first recess. An impurity region is formed at an upper portion of the substrate adjacent to the gate structure.

### CROSS-REFERENCE TO RELATED APPLICATION

This application claims priority under 35 USC § 119 to Korean Patent Application No. 10-2022-0120653, filed on Sep. 23, 2022 in the Korean Intellectual Property Office (KIPO), the contents of which are herein incorporated by reference in their entirety.

### BACKGROUND

### 1. Field

Example embodiments relate to a method of manufacturing a semiconductor device. More particularly, example embodiments relate to a method of forming a transistor.

### 2. Description of the Related Art

A transistor that may be formed on an active pattern of a substrate may include a gate structure and source/drain regions at upper portions of the active pattern adjacent to the gate structure, and a channel may be formed at a portion of the active pattern between the source/drain regions. The performance of the transistor may depend on the characteristics of the channel, and thus a method of enhancing the quality of the channel may be advantageous.

### SUMMARY

Example embodiments provide a method of manufacturing a semiconductor device having enhanced characteristics.

According to example embodiments, there is provided a method of manufacturing a semiconductor device. In the method, a first selective epitaxial growth (SEG) process may be performed on a substrate to form a first channel. A first etching process may be performed to form a first recess through the first channel and an upper portion of the substrate. A sidewall of the first channel exposed by the first recess may be slanted with respect to an upper surface of the substrate. A second SEG process may be performed to form a second channel on a surface of the substrate and the sidewall of the first channel exposed by the first recess. A gate structure may be formed to fill the first recess. An impurity region may be formed at an upper portion of the substrate adjacent to the gate structure.

According to example embodiments, there is provided a method of manufacturing a semiconductor device. In the method, a first selective epitaxial growth (SEG) process may be performed on a substrate to form a first channel. A first etching process may be performed to form a first recess through the first channel and an upper portion of the substrate. A second etching process may be performed on the first channel and an upper portion of the substrate to enlarge a width of the first recess, and the enlarged first recess may form a second recess. A second SEG process may be performed to form a second channel on a surface of the substrate and a sidewall of the first channel exposed by the second recess. A gate structure may be formed to fill the second recess. An impurity region may be formed at an upper portion of the substrate adjacent to the gate structure.

According to example embodiments, there is provided a method of manufacturing a semiconductor device. In the method, a first selective epitaxial growth (SEG) process may be performed on a substrate to form a first channel. A first etching process may be performed to form a first recess through the first channel and an upper portion of the substrate, and a sidewall of the first channel exposed by the first recess may have a positive slope with respect to an upper surface of the substrate. A second etching process may be performed on the first channel and an upper portion of the substrate to enlarge a width of the first recess, and the enlarged first recess may form a second recess. A sidewall of the first channel exposed by the second recess may have a negative slope with respect to the upper surface of the substrate. A second SEG process may be performed to form a second channel on a surface of the substrate and the sidewall of the first channel exposed by the second recess. A gate structure may be formed to fill the second recess. An impurity region may be formed at an upper portion of the substrate adjacent to the gate structure.

A PMOS transistor formed by the method in accordance with example embodiments may include a silicon-germanium channel, and thus may have a lower threshold voltage and/or a lower negative bias temperature instability (NBTI). Accordingly, the PMOS transistor may have an enhanced reliability.

The PMOS transistor may include a channel structure having a constant or more constant thickness, so that the PMOS transistor may have enhanced electric characteristics.

### BRIEF DESCRIPTION OF THE DRAWINGS

FIG. 1 is a cross-sectional view illustrating a semiconductor device in accordance with example embodiments.

FIGS. 2 to 7 are cross-sectional views illustrating a method of manufacturing a semiconductor device.

FIG. 8 is a cross-sectional view illustrating a semiconductor device in accordance with example embodiments.

FIG. 9 is a cross-sectional view illustrating a method of manufacturing a semiconductor device in accordance with example embodiments.

### DESCRIPTION OF EMBODIMENTS

A semiconductor device and a method of manufacturing the same in accordance with example embodiments will be described more fully hereinafter with reference to the accompanying drawings. It will be understood that, although the terms “first,” “second,” and/or “third” may be used herein to describe various elements, these elements should not be limited by these terms. These terms are only used to distinguish one element from another element.

FIG. 1 is a cross-sectional view illustrating a semiconductor device in accordance with example embodiments.

Referring to FIG. 1, the semiconductor device may include a channel structure 130, a gate structure and/or impurity regions 190.

The semiconductor device may further include an active pattern 105, an isolation pattern 110 and/or a gate spacer 180.

The substrate 100 may include a semiconductor material, e.g., silicon, germanium, silicon-germanium, etc., or III-V semiconductor compounds, e.g., GaP, GaAs, GaSb, etc. In some embodiments, the substrate 100 may include a silicon-on-insulator (SOI) substrate or a germanium-on-insulator (GOI) substrate.

The active pattern 105 may be formed on the substrate 100, and a sidewall of the active pattern 105 may be covered by an isolation pattern 110. The active pattern 105 may be defined on the substrate 100 by partially removing an upper portion of the substrate 100 to form a first recess, and thus the active pattern 105 may include the same or substantially the same material as the substrate 100. The isolation pattern 110 may include an oxide, e.g., silicon oxide.

In example embodiments, the channel structure 130 may include first and second channels 120 and 125. The second channel 125 may be formed on a surface of the active pattern 105 exposed by a third recess 152 (refer to FIG. 4), and the first channel 120 may be formed on an upper surface of a portion of the active pattern 105 on which the third recess 152 is not formed.

Each of the first and second channels 120 and 125 may include single crystalline silicon-germanium. The first and second channels 120 and 125 may contact each other, and in some embodiments, the first and second channels 120 and 125 may be merged with each other. In example embodiments, a germanium concentration of the first channel 120 may be substantially equal to a germanium concentration of the second channel 125. Alternatively, a germanium concentration of the first channel 120 may be different from a germanium concentration of the second channel 125.

In example embodiments, a sidewall of the first channel 120 contacting the second channel 125 may be slanted with respect to an upper surface of the substrate 100, and may have a negative slope. That is, the sidewall of the first channel 120 contacting the second channel 125 and the upper surface of the substrate 100 or the upper surface of the active pattern 105 may form an obtuse angle.

In example embodiments, a portion of the second channel 125 contacting the sidewall of the first channel 120 may have a thickness the same or substantially the same as or similar to a thickness of other portions of the second channel 125. In example embodiments, the first channel 120 may have a thickness the same or substantially the same as or similar to a thickness of the second channel 125. Thus, the channel structure 130 including the first and second channels 120 and 125 may have a constant or more constant thickness.

The gate structure may be formed on the channel structure 130, and may fill the third recess 152 and protrude upwardly from the active pattern 105. The gate structure may include a gate insulation pattern 155, a gate electrode 165 and/or a gate mask 175 sequentially stacked in a vertical direction substantially perpendicular to the upper surface of the substrate 100, and a gate spacer 180 may be formed on a sidewall of the gate structure.

The gate insulation pattern 155 may include an oxide, e.g., silicon oxide, the gate electrode 165 may include, e.g., a metal, a metal nitride, a metal silicide, doped polysilicon, etc., and each of the gate mask 175 and the gate spacer 180 may include an insulating nitride, e.g., silicon nitride.

The impurity region 190 may include silicon doped with p-type impurities, e.g., boron, and may be formed at an upper portion of the active pattern 105 adjacent to the gate spacer 180.

The gate structure, the channel structure 130 under the gate structure, and/or the impurity regions 190 at upper portions of the active pattern 105 adjacent to the gate structure may form a transistor, more particularly, a recess channel array transistor (RCAT), and each of the impurity regions 190 may serve as a source/drain of the transistor. Each of the impurity regions 190 may include p-type impurities, and thus the transistor may be a PMOS transistor.

The PMOS transistor may include the channel structure 130 containing silicon-germanium, and thus may have enhanced electric characteristics when compared to a channel containing silicon.

That is, as the PMOS transistor includes the channel structure 130 containing silicon-germanium of which a bandgap is less than a bandgap of silicon, a hole barrier height of the channel structure 130 may increase so that an amount of holes trapped in the gate insulation pattern 150 including silicon oxide may decrease. Thus, a threshold voltage of the transistor may decrease. Additionally, an NBTI of the transistor may decrease so as to enhance a reliability of the transistor.

In example embodiments, the channel structure 130 may be formed under the gate structure, and may have a constant or more constant thickness. Thus, the electric characteristics of the PMOS transistor including the channel structure 130 may be enhanced, and/or the reliability of the PMOS transistor may be enhanced.

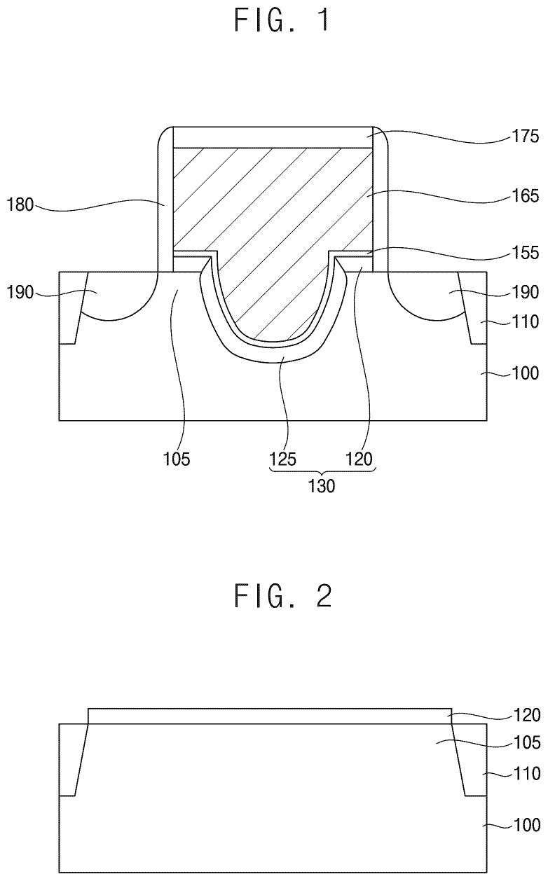

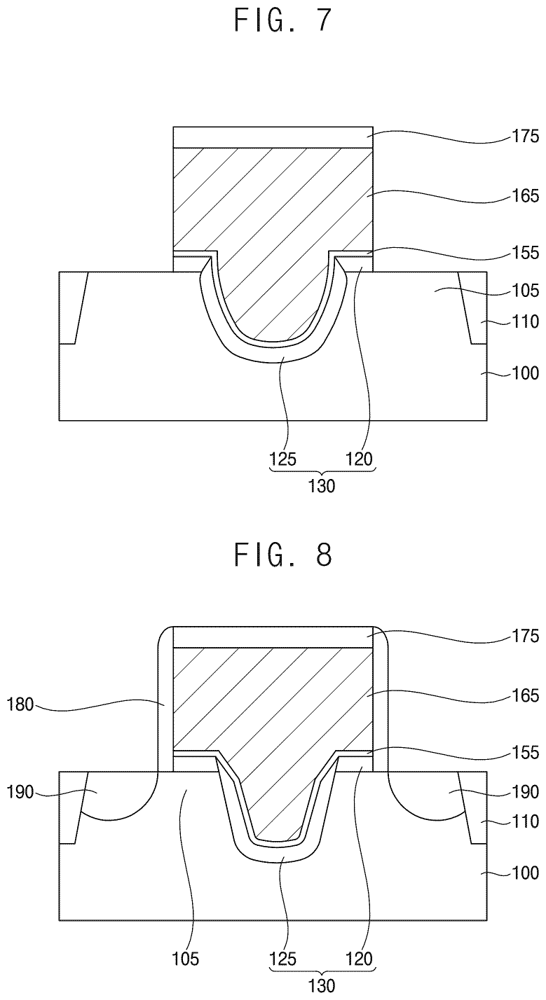

FIGS. 2 to 7 are cross-sectional views illustrating a method of manufacturing a semiconductor device.

Referring to FIG. 2, an active pattern 105 may be formed on a substrate 100, and an isolation pattern 110 may be formed on the substrate 100 to cover a sidewall of the active pattern 105.

The active pattern 105 may be formed by partially removing an upper portion of the substrate 100 to form a first recess.

A first selective epitaxial growth (SEG) process may be performed using an upper surface of the active pattern 105 as a seed to form a first channel 120 on the active pattern 105.

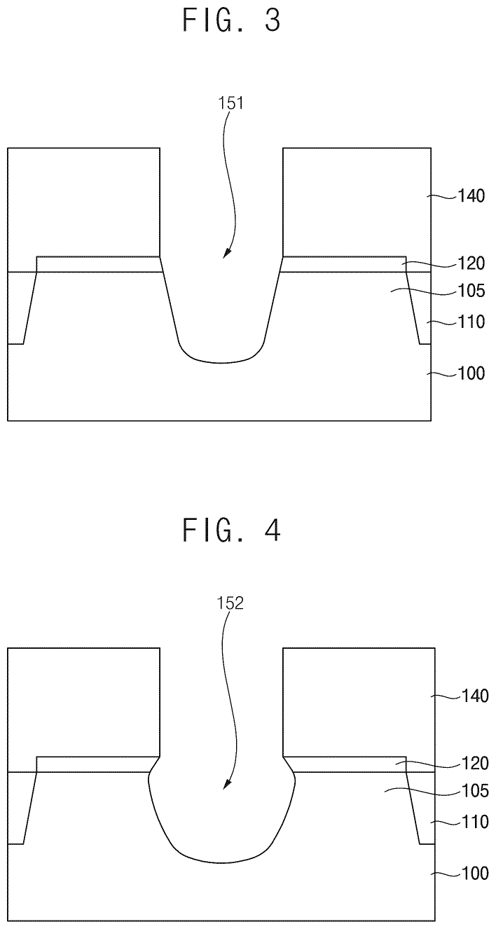

Referring to FIG. 3, a mask 140 may be formed on the first channel 120 and the isolation pattern 110 to partially expose an upper surface of the first channel 120, and a first etching process may be performed using the mask 140 as an etching mask.

By the first etching process, the first channel 120 and the active pattern 105 may be partially removed to form a second recess 151. In example embodiments, the first etching process may be an anisotropic etching process, and may include a dry etching process or a wet etching process.

In example embodiments, a width of the second recess 151 may gradually decrease from a top toward a bottom thereof. Thus, a sidewall of the first channel 120 exposed by the second recess 151 may be slanted with respect to the upper surface of the substrate 100, and may have a positive slope.

Referring to FIG. 4, a second etching process may be performed on the first channel 120 and the active pattern 105, so that a width of the second recess 151 may be enlarged to form a third recess 152.

In example embodiments, the second etching process may be an isotropic etching process, and may include a wet etching process or a dry etching process. During the second etching process, an etch rate of the first channel 120 may be greater than an etch rate of the active pattern 105, and thus the second etching process may be performed for a short time so that the first channel 120 may not be excessively etched by the second etching process. In example embodiments, a width of the third recess 152 may gradually increase and then gradually decrease from a top toward a bottom thereof. Thus, a sidewall of the first channel 120 exposed by the third recess 152 may have a negative slope.

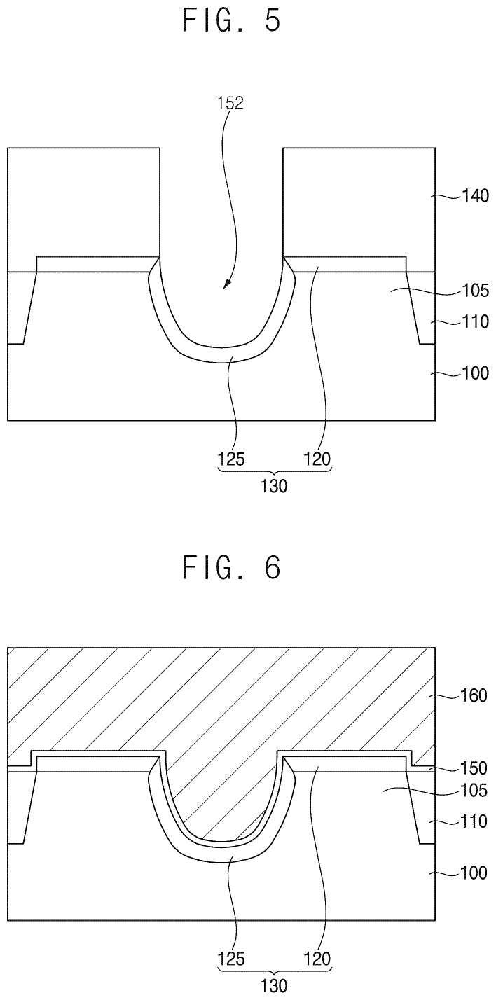

Referring to FIG. 5, a second SEG process may be performed using a surface of the active pattern 105 exposed by the third recess 152 and the sidewall of the first channel 120 as a seed to form a second channel 125.

In example embodiments, the second channel 125 may contact the sidewall of the first channel 120 to be connected thereto, and may have a constant or more constant thickness on the surface of the active pattern 105. The connected first and second channels 120 and 125 may form a channel structure 130.

Referring to FIG. 6, after removing the mask 140 to expose upper surfaces of the first channel 120 and the isolation pattern 110, a gate insulation layer 150 may be formed on the upper surfaces of the channel structure 130 and the isolation pattern 110, and a gate electrode layer 160 and a gate mask layer may be sequentially formed on the gate insulation layer 150.

The gate mask layer may be patterned to form a gate mask 175 and a third etching process may be performed on the gate electrode layer 160, the gate insulation layer 150 and the first channel 120 using the gate mask 175 as an etching mask.

Thus, a gate structure including a gate insulation pattern 155, a gate electrode 165 and a gate mask 175 sequentially stacked in a vertical direction substantially perpendicular to the upper surface of the substrate 100 may be formed on the channel structure 130 to fill the third recess 152.

Referring to FIG. 1 again, a gate spacer 180 may be formed on a sidewall of the gate structure, and an ion implantation process may be performed on upper portions of the active pattern 105 not covered by the gate structure and the gate spacer 180 to form an impurity regions 190 at opposite sides, respectively, of the gate structure.

In example embodiments, each of the impurity regions 190 may be formed by doping n-type impurities, e.g., boron.

The gate structure, the impurity regions 190 and the channel structure 130 may collectively form a transistor, and each of the impurity regions 190 may serve as a source/drain of the transistor.

By the above processes, the semiconductor device including the transistor may be manufactured.

As illustrated above, the first SEG process may be performed to form the first channel 120 on the upper surface of the active pattern 105, the first etching process may be performed on the first channel 120 and the active pattern 105 to form the second recess 151, the second recess 151 may be enlarged to form the third recess 152, and the second SEG process may be performed to form the second channel 125 on the surface of the active pattern 105 exposed by the third recess 152 and the sidewall of the first channel 120. Thus, the channel structure 130 including the first and second channels 120 and 125 may be formed to have a constant or more constant thickness.

If a conventional etching process is performed on the active pattern 105 to form a recess, and a conventional SEG process is performed on the active pattern 105 to form a channel, due to the characteristics of the SEG process, facet may be generated in the channel on an upper sidewall of the recess according to a surface direction of the recess.

Thus, a portion of the channel on the upper sidewall of the recess may have a thickness less than a thickness of a portion of the channel on a lower sidewall of the recess or on an upper surface of the active pattern on which the recess is not formed, which may deteriorate the characteristics of the channel.

However, in example embodiments, the first SEG process may be performed on the upper surface of the active pattern 105 to form the first channel 120, and the second and third recesses 151 and 152 may be formed, and the second SEG process may be performed to form the second channel 125 on the surface of the active pattern 105 exposed by the third recess 152 and the sidewall of the first channel 120, so that the second channel 125 may have a constant or more constant thickness even on the upper sidewall of the third recess 152 and that the channel structure 130 including the first channel 120 and the second channel 125 connected to the first channel 120 may have a constant or more constant thickness.

For example, the third recess 152 may be formed by enlarging the second recess 151 through the second etching process, so that the sidewall of the first channel 120 having a positive slope may be changed to the sidewall of the first channel 120 having a negative slope, and thus the portion of the second channel 125 on the upper sidewall of the third recess 152 may have an increased thickness.

FIG. 8 is a cross-sectional view illustrating a semiconductor device in accordance with example embodiments, which may correspond to FIG. 1.

This semiconductor device may be the same or substantially the same as or similar to that of FIG. 1, except for the shape of the channel structure 130. Thus, like reference numerals refer to like elements, and repeated explanations thereof are omitted herein.

Referring to FIG. 8, the sidewall of the first channel 120 contacting the second channel 125 may have a positive slope. That is, the sidewall of the first channel 120 contacting the second channel 125 and the upper surface of the substrate 100 or the upper surface of the active pattern 105 may form an acute angle.

In example embodiments, a portion of the second channel 125 contacting the sidewall of the first channel 120 may have a thickness less than a thickness of the other portions of the second channel 125, however, the channel structure 130 including the first and second channels 120 and 125 may have a constant or a more constant thickness.

That is, the second channel 125 may contact the first channel 120 to be connected thereto, and a portion of the channel structure 130 including the first and second channels 120 and 125 on the upper sidewall of the second recess 151 may have a thickness similar to a thickness of other portions of the channel structure 130.

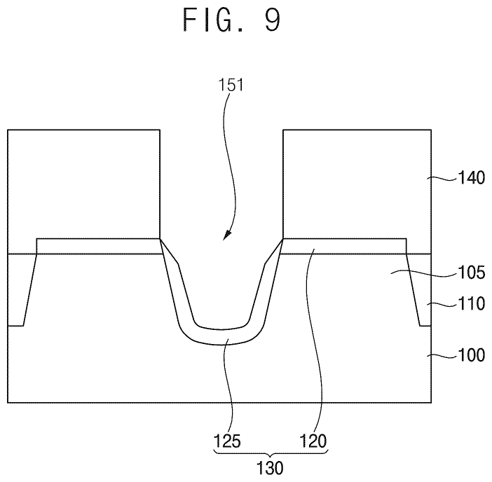

FIG. 9 is a cross-sectional view illustrating a method of manufacturing a semiconductor device in accordance with example embodiments.

This method may include processes the same or substantially the same as or similar to those illustrated with reference to FIGS. 2 to 7 and FIG. 1, and thus repeated explanations are omitted herein.

Referring to FIG. 9, processes the same or substantially the same as or similar to those illustrated with reference to FIGS. 2 and 3 may be performed to form the second recess 152, and the second SEG process illustrated with reference to FIG. 5 may be performed without performing the second etching process illustrated with reference to FIG. 4.

Thus, the second channel 125 may be formed on the surface of the active pattern 105 exposed by the second recess 151 and the sidewall of the first channel 120.

As the second etching process is not performed, the sidewall of the first channel 120 exposed by the second recess 151 may keep the positive slope, and thus a portion of the second channel 125 on the upper sidewall of the second recess 151 may have a relatively small thickness after the second. SEG process.

However, the first channel 120 has been formed on the upper surface of the active pattern 105, and thus the second channel 125 may contact the first channel 120 to be connected thereto, and thus a portion of the channel structure 130 including the first and second channels 120 and 125 on the upper sidewall of the second recess 151 may have a thickness similar to a thickness of other portions of the channel structure 130.

Processes the same or substantially the same as or similar to those illustrated with reference to FIGS. 6 to 7 and FIG. 1 may be performed to complete the fabrication of the semiconductor device.

The semiconductor device may be used in various types of memory devices and/or systems including transistors. For example, the semiconductor device may be applied to a logic device such as a central processing unit (CPU), an application processor (AP), etc. Alternatively, the semiconductor device may be applied to a volatile memory device such as a DRAM device, an SRAM device, etc., or to a non-volatile memory device such as a flash memory device, a PRAM device, an MRAM device, an RRAM device, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concepts. Accordingly, all such modifications are intended to be included within the scope of the present inventive concepts as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of manufacturing a semiconductor device, the method comprising:
performing a first selective epitaxial growth (SEG) process on a substrate to form a first channel;
performing a first etching process to form a first recess through the first channel and an upper portion of the substrate, a sidewall of the first channel exposed by the first recess being slanted with respect to an upper surface of the substrate;
performing a second SEG process to form a second channel on a surface of the substrate and the sidewall of the first channel exposed by the first recess;
forming a gate structure to fill the first recess; and
forming an impurity region at an upper portion of the substrate adjacent to the gate structure.

2. The method as claimed in claim 1, wherein the sidewall of the first channel exposed by the first recess has a positive slope with respect to the upper surface of the substrate.

3. The method as claimed in claim 2, further comprising, after performing the first etching process, performing a second etching process on the first channel and an upper portion of the substrate to enlarge a width of the first recess, the enlarged first recess forming a second recess.

4. The method as claimed in claim 3, wherein a sidewall of the first channel exposed by the second recess has a negative slope with respect to the upper surface of the substrate.

5. The method as claimed in claim 3, wherein the second etching process includes an isotropic etching process.

6. The method as claimed in claim 1, further comprising, after forming the first channel, forming an etching mask on the first channel,
wherein the first etching process includes an isotropic etching process using the etching mask.

7. The method as claimed in claim 1, wherein each of the first and second channels includes silicon-germanium.

8. The method as claimed in claim 7, wherein the second channel is formed to contact the sidewall of the first channel.

9. The method as claimed in claim 7, wherein a germanium concentration of the first channel is different from a germanium concentration of the second channel.

10. The method as claimed in claim 1, wherein forming the impurity region includes doping p-type impurities into the substrate.

11. A method of manufacturing a semiconductor device, the method comprising:
performing a first selective epitaxial growth (SEG) process on a substrate to form a first channel;
performing a first etching process to form a first recess through the first channel and an upper portion of the substrate;
performing a second etching process on the first channel and an upper portion of the substrate to enlarge a width of the first recess, the enlarged first recess forming a second recess;
performing a second SEG process to form a second channel on a surface of the substrate and a sidewall of the first channel exposed by the second recess;
forming a gate structure to fill the second recess; and
forming an impurity region at an upper portion of the substrate adjacent to the gate structure.

12. The method as claimed in claim 11, wherein a sidewall of the first channel exposed by the first recess has a positive slope with respect to the upper surface of the substrate.

13. The method as claimed in claim 12, wherein a sidewall of the second channel exposed by the second recess has a negative slope with respect to the upper surface of the substrate.

14. The method as claimed in claim 11, further comprising, after forming the first channel, forming an etching mask on the first channel,
wherein the first etching process includes an isotropic etching process using the etching mask.

15. The method as claimed in claim 11, wherein the second etching process includes an isotropic etching process.

16. The method as claimed in claim 11, wherein each of the first and second channels includes silicon-germanium.

17. The method as claimed in claim 16, wherein a germanium concentration of the first channel is different from a germanium concentration of the second channel.

18. The method as claimed in claim 11, wherein the second channel is formed to contact a sidewall of the first channel.

19. A method of manufacturing a semiconductor device, the method comprising:
performing a first selective epitaxial growth (SEG) process on a substrate to form a first channel;
performing a first etching process to form a first recess through the first channel and an upper portion of the substrate, a sidewall of the first channel exposed by the first recess having a positive slope with respect to an upper surface of the substrate;
performing a second etching process on the first channel and an upper portion of the substrate to enlarge a width of the first recess, the enlarged first recess forming a second recess, and a sidewall of the first channel exposed by the second recess having a negative slope with respect to the upper surface of the substrate;
performing a second SEG process to form a second channel on a surface of the substrate and the sidewall of the first channel exposed by the second recess;
forming a gate structure to fill the second recess; and
forming an impurity region at an upper portion of the substrate adjacent to the gate structure.

20. The method as claimed in claim 19, wherein each of the first and second channels includes silicon-germanium.
